(19) United States
(12) Patent Application Publication
(10) Pub. No.: US 2025/0006701 A1
(43) Pub. Date: Jan. 2, 2025

(54) SEMICONDUCTOR DIE STACKING ARCHITECTURE AND CONNECTION METHOD THEREFORE

(71) Applicant: Western Digital Technologies, Inc., San Jose, CA (US)

(72) Inventors: Nagesh Vodrahalli, Los Altos, CA (US); Chih Yang Li, Menlo Park, CA (US); Rama Kant Shukla, Saratoga, CA (US)

(21) Appl. No.: 18/360,555

(22) Filed: Jul. 27, 2023

Related U.S. Application Data
(60) Provisional application No. 63/510,912, filed on Jun. 29, 2023.

(51) Int. Cl. H01L 25/065; H01L 23/00; H01L 23/48

(52) U.S. Cl. CPC H01L 25/0657; H01L 23/481; H01L 24/09; H01L 24/48; H01L 2224/48149; H01L 2224/48249; H01L 2225/06541

(57) ABSTRACT

Semiconductor dies in a stack of semiconductor dies are interconnected using metal lines instead of bond wires or through silicon vias (TSVs). The semiconductor dies in the stack are arranged in a stairstep configuration such that a step corner is defined between a top surface of a first semiconductor die in the stack and a sidewall of a second semiconductor die in the stack. A step ramp is formed in the step corner. The step ramp defines a slope that extends between the top surface of the first semiconductor die and a top surface of the second semiconductor die. A metal line is formed over a bond pad associated with the first semiconductor die, the step ramp and a bond pad associated with the second semiconductor die.

### CROSS-REFERENCE TO RELATED APPLICATIONS

The present application claims priority to U.S. Provisional Application 63/510,912 entitled “SEMICONDUCTOR DIE STACKING ARCHITECTURE AND CONNECTION METHOD THEREFORE”, filed Jun. 29, 2023, the entire disclosure of which is hereby incorporated by reference in its entirety.

### BACKGROUND

Die stacking is a process in which multiple semiconductor dies are stacked on top of each other and are interconnected to form a single unit. In current die stacking architectures, bond wires or through silicon vias (TSVs) are used to connect the different semiconductor dies in the semiconductor stack.

However, bond wires may limit the performance capabilities of the semiconductor stack. For example, bond wires are typically associated with one or more parasitic effects that prevent the semiconductor stack from performing at a very high level. While TSVs may be used in place of bond wires and enable the semiconductor stack to perform at a very high level, forming TSVs in the various semiconductor dies of the semiconductor stack is expensive in terms of both time and cost.

Accordingly, it would be beneficial to interconnect semiconductor dies of a semiconductor stack without using bond wires or TSVs while enabling the semiconductor stack to achieve high performance capabilities.

### SUMMARY

The present application describes an architecture for stacking semiconductor dies and interconnecting the semiconductor dies with metal lines (also referred to herein as “transmission lines”) instead of using bond wires or through silicon vias (TSVs). When compared to bond wires, the metal lines are not as susceptible to parasitic effects. The metal lines are also cheaper to manufacture when compared to TSVs. The metal lines may also enable the stack of semiconductor dies to perform at a level that is comparable to a stack of semiconductor dies that are interconnected using TSVs.

As will be described in greater detail herein, semiconductor dies are arranged in a stack and may be used in a semiconductor package. The stack of semiconductor dies may be arranged in a stairstep configuration such that a step corner is formed or defined between a top surface of a first semiconductor die in the stack and a sidewall of a second semiconductor die in the stack. A step ramp is formed in the step corner. The step ramp defines a slope that extends between the top surface of the first semiconductor die and a top surface of the second semiconductor die. A metal line is formed over a bond pad associated with the first semiconductor die, the step ramp and a bond pad associated with the second semiconductor die.

Because the metal line extends on the slope of the step ramp, an interconnect length between the bond pad associated with the first semiconductor die and the bond pad associated with the second semiconductor die is shorter when compared to an interconnect length using a bond wire. Additionally, use of metal lines instead of bond wires enables the use of smaller bond pads. Smaller bond pads also enables a smaller/tighter pitch between the various bond pads on a particular semiconductor die. As such, more interconnects may be made between the various semiconductor dies. As a result, the semiconductor package may perform at a higher level/frequency when compared with semiconductor packages that utilize bond wires.

Accordingly, examples of the present disclosure describe a stack of semiconductor dies for a semiconductor package. In an example, the stack of semiconductor dies is formed by a first semiconductor die and a second semiconductor die. The first semiconductor die and the second semiconductor die define a step corner between a surface of the first semiconductor die and a sidewall of the second semiconductor die. A step ramp is formed in the step corner. A transmission line is formed over a first bond pad associated with the first semiconductor die, the step ramp and a second bond pad associated with the second semiconductor die.

The present application also describes a method for fabricating a stack of semiconductor dies for a semiconductor package. In an example, the method includes stacking a second semiconductor die on a first semiconductor die to form a semiconductor die stack. The semiconductor die stack defines a step corner between a surface of the first semiconductor die and a sidewall of the second semiconductor die. A step ramp is formed in the step corner. Additionally, a transmission line is formed over a first bond pad associated with the first semiconductor die, the step ramp and a second bond pad associated with the second semiconductor die.

In another example, the present application describes a semiconductor package that includes a stack of semiconductor dies formed by a first semiconductor die and a second semiconductor die. In an example, the first semiconductor die and the second semiconductor die define a step corner between a surface of the first semiconductor die and a sidewall of the second semiconductor die. The semiconductor package also includes a ramp means formed in the step corner and a transmission means. The transmission means is formed over a first connection means associated with the first semiconductor die, the ramp means and a second connection means associated with the second semiconductor die.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates a stack of semiconductor dies for a semiconductor package according to an example.

FIG. 2 illustrates a first operation in a fabrication process in which a number of semiconductor dies are stacked together to form a stack of semiconductor dies according to an example.

FIG. 3 illustrates a second operation in the fabrication process in which a step ramp is formed in each step corner of the stack of semiconductor dies according to an example.

FIG. 4 illustrates a third operation in the fabrication process in which a photoresist layer is provided on the stack of semiconductor dies according to an example.

FIG. 5 illustrates a fourth operation in the fabrication process in which a patterning process is used to write or expose one or more patterns on the bond pads and/or the step ramps of the stack of semiconductor dies according to an example.

FIG. 6 illustrates a fifth operation in the fabrication process in which a metal layer is deposited on the exposed bond pads and/or the step ramps of the stack of semiconductor dies according to an example.

FIG. 7 illustrates a sixth operation in the fabrication process in which another photoresist layer is provided on the stack of semiconductor dies according to an example.

FIG. 8 illustrates a seventh operation in the fabrication process in which an electroplating process is performed on the metal layer according to an example.

FIG. 9 illustrates an eighth operation in the fabrication process in which the first photoresist layer and the second photoresist layer are removed from the stack of semiconductor dies according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

Current semiconductor die stacking architectures require the use of bond wires or through silicon vias (TSVs) to connect the various semiconductor dies in a stack of semiconductor dies. However, bond wires are subject to parasitic effects (e.g., resistance, inductance) that may reduce the overall performance of the stack of semiconductor dies. While TSVs address the parasitic effects of bond wires, forming TSVs in a stack of semiconductor dies is time intensive and costly.

In order to address the above, the present application describes a semiconductor die stacking architecture in which metal lines (also referred to herein as “transmission lines”) are used as interconnects instead of bond wires or through silicon vias (TSVs). For example, a semiconductor package includes a stack of semiconductor dies. The semiconductor dies are arranged in a stairstep configuration such that a step corner is defined between a top surface of a first semiconductor die and a sidewall of a second semiconductor die. During manufacturing or fabrication, a step ramp is formed in the step corner. The step ramp defines a slope that extends between the top surface of the first semiconductor die and a top surface of the second semiconductor die. A metal line (or a metal layer) is then formed over a bond pad associated with the first semiconductor die, the step ramp and a bond pad associated with the second semiconductor die.

Replacing bond wires with metal lines decreases a length of the interconnects between the different semiconductor dies in the stack of semiconductor dies. For example, the metal line extends from the bond pad on the first semiconductor die, up (or down) the slope of the step ramp and overlays the bond pad on the second semiconductor die. As such, a length of the interconnect between the bond pads is shorter when compared to an interconnect formed with a bond wire.

Additionally, the metal wire enables the bond pads to be smaller when compared with bond pads that are typically used with bond wires. Because the bond pads are smaller, a pitch between the bond pads may also be smaller when compared to a pitch between bond pads that are used with bond wires. Due to the smaller pitch between bond pads, more bond pads and associated interconnects may be added to the semiconductor stack which helps increase the performance of the semiconductor package. The metal lines may also enable more semiconductor dies to be included in the stack of semiconductor dies when compared with bond wire solutions.

The metal lines are also cheaper to manufacture when compared to TSVs. However, the metal lines may also enable the stack of semiconductor dies to perform at a level that is comparable to a stack of semiconductor dies that are interconnected using TSVs.

Accordingly, the present application describes many technical benefits including, but not limited to, enabling the fabrication of high density semiconductor packages having an increased number of semiconductor dies when compared with current semiconductor packages; increasing the number of interconnects between semiconductor dies in a stack of semiconductor dies; and improving the electrical performance of semiconductor packages when compared with semiconductor packages that use bond wires when making electrical connections.

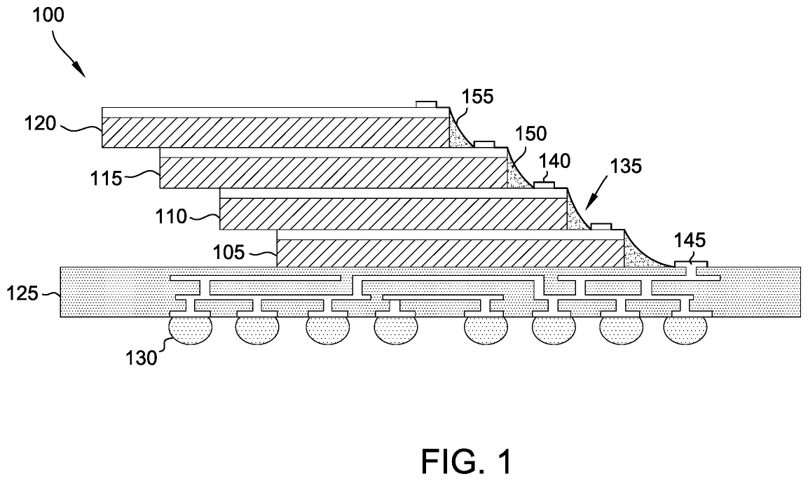

These benefits, along with other examples, will be shown and described in greater detail with respect to FIG. 1-FIG. 9.

FIG. 1 illustrates a stack of semiconductor dies 100 for a semiconductor package according to an example. The stack of semiconductor dies 100 includes a first semiconductor die 105, a second semiconductor die 110, a third semiconductor die 115 and a fourth semiconductor die 120. In an example, each semiconductor die is a memory die such as, for example, a NAND flash memory die. Although a NAND flash memory die is specifically mentioned, the memory die may be any type of volatile or non-volatile memory die. In another example, the stack of semiconductor dies 100 may include any type stackable semiconductor die and/or stackable integrated circuit.

In an example, the first semiconductor die 105 is provided or mounted on a surface of a substrate 125 or a printed circuit board (PCB). The substrate 125 may include or otherwise be associated with one or more conductive balls 130 that enable the semiconductor package to be electrically and/or communicatively coupled to a computing component or an electronic device.

The second semiconductor die 110 is mounted on a top surface of the first semiconductor die 105. In an example, the second semiconductor die 105 is mounted on the first semiconductor die 105 using a die attach film (DAF). Although DAF is specifically mentioned, the second semiconductor die 110 may be mounted on the top surface of the first semiconductor die 105 using other mounting techniques. Likewise, the third semiconductor die 115 is mounted on a top surface of the second semiconductor die 110 and the fourth semiconductor die 120 is mounted on a top surface of the third semiconductor die 115.

Each of the semiconductor dies are stacked on top of each other or are otherwise arranged in a stairstep configuration. As such, a step corner 135 may be defined between a top surface of one semiconductor die and a sidewall of another semiconductor die. For example, a step corner 135 may be defined by a top surface of the first semiconductor die 105 and a sidewall of the second semiconductor die 110. A length and/or a height of the step corner 135 may vary depending on a thickness or height of each semiconductor die, a length of each semiconductor die and/or a position of each semiconductor die with respect to the semiconductor die on which it is stacked.

In an example, a step ramp 150 is provided or otherwise formed in each step corner 135. The step ramp 150 may be comprised of a polymer or other material. The step ramp 150 forms a planar surface (or a substantially planar surface) between a top surface of one semiconductor die and a top surface of another semiconductor die. For example, a step ramp 150 may be formed between the top surface of the first semiconductor die 105 and the sidewall of the second semiconductor die 110.

In an example, the angle of the planar surface of the step ramp 150 is between forty-five degrees and twenty degrees (or less). Although a specific range is given, the angle of the planar surface of the step ramp 150 may be greater than forty-five degrees. In another example, the angle of the planar surface of the step ramp 150 may be based on a number of factors including, but not limited to, a thickness or height of each semiconductor die, a length of each semiconductor die and/or a position of each semiconductor die with respect to the semiconductor die on which it is stacked. Although a planar or a substantially planar surface is described, the surface of the step ramp 150 may be concave or convex.

Each semiconductor die in the stack of semiconductor dies 100 may also include a bond pad 140. The bond pad 140 may be provided on a top surface of each semiconductor die. The bond pad 140 may be used to electrically and/or communicatively couple the semiconductor dies to each other and/or to a substrate finger 145 provided on the substrate 125. Although FIG. 1 illustrates a single bond pad 140 on each semiconductor die, each semiconductor die may include multiple bond pads 140. In an example, a pitch between the bond pads 140 on a particular semiconductor die may be between forty micrometers (μm) and thirty μm (or less). In contrast, a pitch between bond pads of a stack of semiconductor dies in which bond wires are used is typically between eighty μm and one hundred μm.

As previously indicated, the stack of semiconductor dies 100 does not use bond wires, TSVs, or solder connections to interconnect each semiconductor die. As such, higher performance, lower cost and higher density stacking may be achieved when compared with stacks of semiconductor dies that use bond wires, TSVs and/or solder connections.

To achieve higher performance and higher density stacking at a lower cost, a metal line 155 is provided over the bond pads 140 and the step ramp 150 associated with each semiconductor die. For example, the metal line 155 may form a transmission line, or an interconnect, between the bond pad 140 on the first semiconductor die 105 and the bond pad 140 on the second semiconductor die 110. The metal line 155 may also extend up (or down) the step ramp 150 provided between the first semiconductor die 105 and the second semiconductor die 110. The metal line 155 may also connect the bond pads 140 of the various semiconductor dies to the substrate finger 145.

Because the metal line 155 extends up (or down) each step ramp 150, a shorter interconnect distance is achieved when compared with an interconnect distance using bond wires. Additionally, the metal line 155 enables the bond pads 140 to be spaced closer together (e.g., a pitch between forty micrometers (μm) and thirty μm (or less)) such as previously described. Smaller pitch between the bond pads 140 means that additional bond pads 140, and associated transmission lines, may be added to the stack of semiconductor dies 100. Additional transmission lines may enable higher performance capabilities when compared with a stack of semiconductor dies that are communicatively coupled using bond wires. Using metal lines 155 instead of bond wires may also enable more semiconductor dies to be added to a stack when compared with current bond wire solutions.

In an example, the metal line 155 may be formed from copper. Although copper is specifically mentioned, other materials may be used. In another example, the metal line 155 is plated with copper (e.g., using a copper electroplating process).

In an example, the stack of semiconductor dies 100 may also include an additional metal layer or a ground plane. In one example, the additional metal layer may be used to construct the ground plane. For example, the ground plane may be positioned under the metal lines 155 and/or under the step ramp 150. In another example, the ground plane may be used to form a transmission line. In such examples, the ground plane may increase the signal integrity of interconnect lines that connect the various semiconductor dies in the stack of semiconductor dies 100 to the substrate 125.

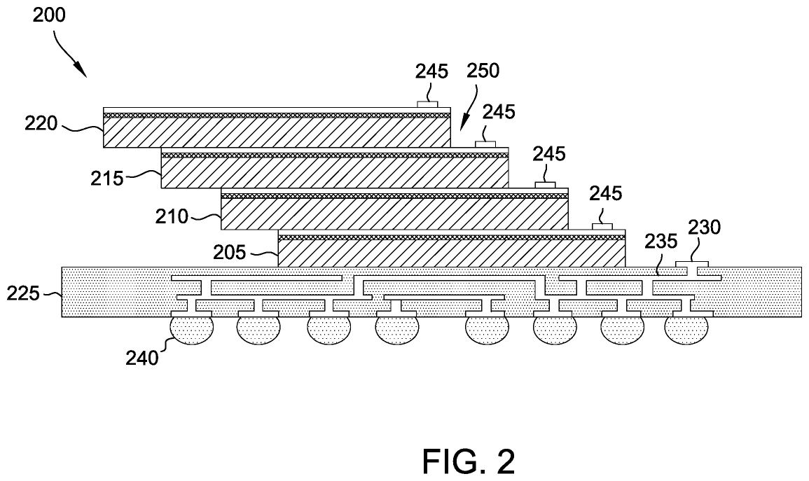

FIG. 2-FIG. 9 show and describe various operations for fabricating a stack of semiconductor dies in which the semiconductor dies of the stack are interconnected without bond wires, TSVs or solder connections. In an example, the various operations described with respect to FIG. 2-FIG. 9 may be used to manufacture the stack of semiconductor dies 100 shown and described with respect to FIG. 1.

FIG. 2 illustrates a first operation in a fabrication process in which a number of semiconductor dies are stacked together to form a stack of semiconductor dies 200 according to an example. As shown in FIG. 2, the semiconductor dies are stacked on top of each other and are arranged in a stairstep configuration.

For example, a first semiconductor die 205 is stacked on, or is otherwise coupled to, a substrate 225. A second semiconductor die 210 may be stacked on, or otherwise coupled to, a top surface of the first semiconductor die 205. Likewise, a third semiconductor die 215 may be stacked on the second semiconductor die 210 and a fourth semiconductor die 220 may be stacked on the third semiconductor die 215. Although four semiconductor dies are shown and described, any number of semiconductor dies may be stacked on top of each other to form the stack of semiconductor dies 200. Additionally, although semiconductor dies are specifically mentioned, the stack of semiconductor dies 200 may include any type of stackable semiconductor die and/or stackable integrated circuit.

In an example, each semiconductor die may be attached to another semiconductor die (or to the substrate 225) using a die attach film (DAF). Although a DAF is specifically mentioned, other materials and/or processes may be used to create the stack of semiconductor dies 200 and/or secure the semiconductor dies to each other and/or to the substrate 225.

When the semiconductor dies are stacked in the stairstep configuration, a step corner 250 is defined. For example, when the second semiconductor die 210 is stacked on the first semiconductor die 205, a step corner 250 is defined between a top surface of the first semiconductor die 205 and a sidewall of the second semiconductor die 210. Similar step corners 250 may be defined between the substrate 225 and the first semiconductor die 205, between the second semiconductor die 210 and the third semiconductor die 215 and between the third semiconductor die 215 and the fourth semiconductor die 220.

Each semiconductor die may also include a bond pad 245. For example, the first semiconductor die 205 may include a bond pad 245, the second semiconductor die 210 may include a bond pad 245 and so on. The bond pad 245 may be formed from a conductive material such as, for example, copper, silver, gold, solder or another material or a combination of materials.

The substrate 225 may also include a bond pad or other connection mechanism (e.g., a substrate finger 230). The substrate finger 230 may be electrically and/or communicatively coupled to one or more traces 235 formed in, or otherwise associated with, the substrate 225. The traces 235 may also be communicatively and/or electrically coupled to one or more solder balls 240 provided on a bottom surface of the substrate 225. Although solder balls 240 are specifically mentioned, other connection mechanisms may be used to electrically and/or communicatively couple the substrate 225 to an electronic device or component.

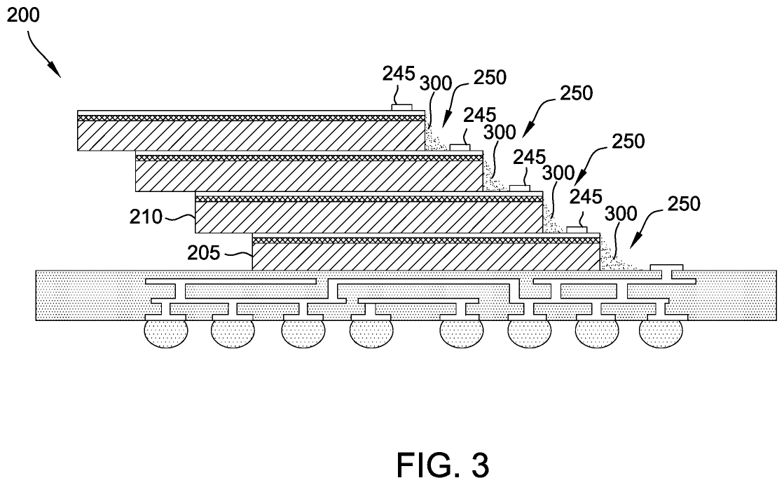

FIG. 3 illustrates a second operation in the fabrication process in which a step ramp 300 is formed in each step corner 250 of the stack of semiconductor dies 200 according to an example. In an example, the step ramp 300 is formed from a polymer or other material. The step ramp 300 may be used to form a planar or a substantially planar surface within each step corner 250 defined by the stack of semiconductor dies 200. Although a planar or a substantially planar surface is specifically mentioned, the surface of the step ramp 250 may be concave or convex.

In an example, the surface of the step ramp 300 may have an angle of approximately forty-five degrees or less. However, the angle of the planar surface of the step ramp 300 may be based on a number of factors such as previously described.

The step ramp 300 may provide a shortest path between the various bond pads 245 of the different semiconductor dies in the stack of semiconductor dies 200. In addition, the step ramp 300 may also be used to prevent a short from occurring between a metal line or a transmission line and the silicon from which the semiconductor dies are formed.

In an example, the step ramp 300 may extend from (or near) a bond pad 245 on a top surface of the first semiconductor die 205 and up or along a sidewall of the second semiconductor die 210. The step ramp 300 may also extend around a top corner of the sidewall of the second semiconductor die 210 and at least partially along a top surface of the second semiconductor die 210 (e.g., at least partially to the bond pad 245 on the top surface of the second semiconductor die 210).

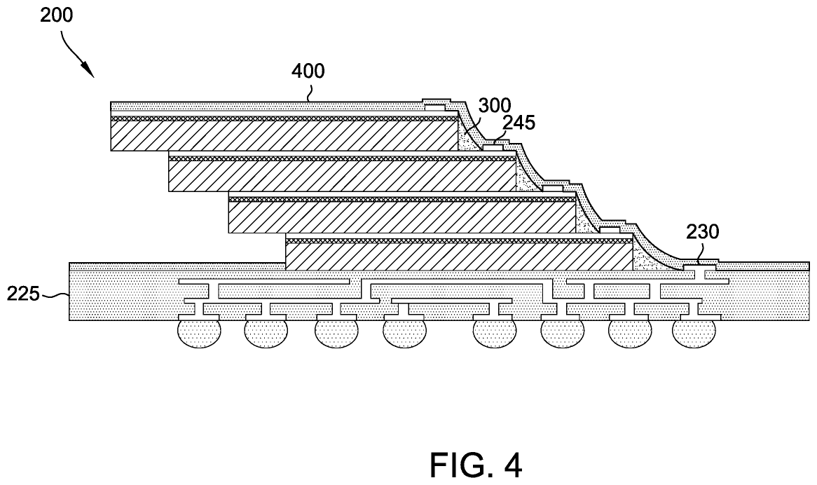

FIG. 4 illustrates a third operation in the fabrication process in which a photoresist layer 400 is provided over the stack of semiconductor dies 200 according to an example. As shown in FIG. 4, the photoresist layer 400 may be provided over exposed portions of the substrate 225, the step ramp 300, the bond pads 245 and/or the substrate finger 230. In an example, the photoresist layer 400 is provided over the stack of semiconductor dies 200 using a spraying process. The spraying process may be used to achieve a uniform, or a substantially uniform, thickness. Although a spraying process is specifically mentioned, the photoresist layer 400 may be provided over the stack of semiconductor dies 200 using any suitable technique.

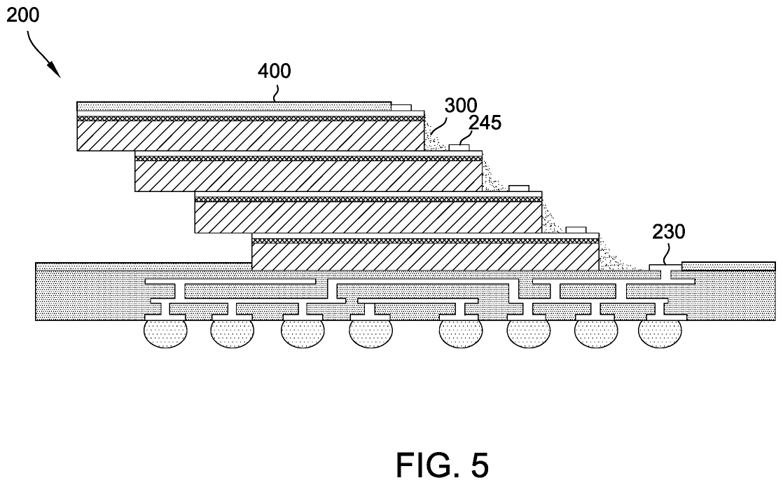

FIG. 5 illustrates a fourth operation in the fabrication process in which a patterning process is used to write or expose one or more patterns on the bond pads 245 and/or the step ramps 300 of the stack of semiconductor dies 200 according to an example. The patterning process may also be used to write or expose one or more patterns on the substrate finger 230.

In an example, the patterning process uses a laser (e.g., laser lithography) or an ultraviolet light to create the pattern or otherwise expose the bond pads 245, the substrate finger 230 and/or the step ramps 300 for further processing. In an example, a laser writer or other mechanism that performs the patterning process may move in an XY direction and in a Z direction to account for changes in the height of the stack of semiconductor dies 200.

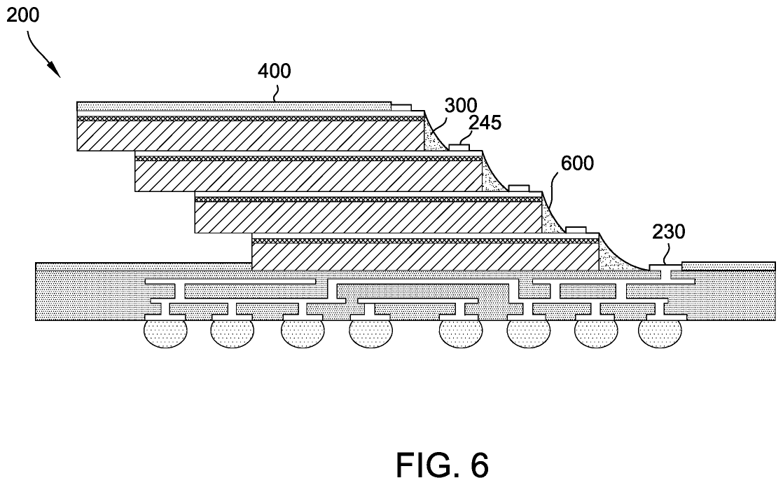

FIG. 6 illustrates a fifth operation in the fabrication process in which a metal layer 600 is deposited on the exposed bond pads 245 and/or the step ramps 300 of the stack of semiconductor dies 200 according to an example. The metal layer 600 may also be provided on the substrate finger 230 and/or any exposed photoresist layer 400.

In an example, the metal layer 600 is used to form transmission lines, metal lines or interconnects for the stack of semiconductor dies 200. The metal layer 600 may be deposited or otherwise formed on the bond pads 245 and/or the step ramps 300 using vacuum deposition process. Although a vacuum deposition process is specifically mentioned, other thin metal deposition processes may be used.

The metal layer 600 may be formed from copper. Although copper is specifically mentioned, other conductive materials, such as gold, silver or a combination of conductive materials, may be used to form the metal layer 600.

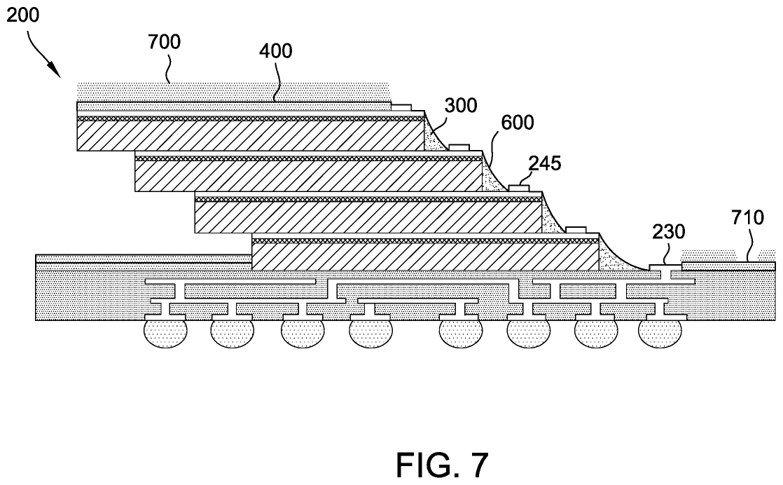

FIG. 7 illustrates a sixth operation in the fabrication process in which another photoresist layer 700 is provided over the stack of semiconductor dies 200 according to an example. In addition to adding a second photoresist layer 700, a second patterning process may also be used to write or expose one or more patterns on the metal layer 600 that was formed over the bond pads 245, the step ramp 300 and/or the substrate finger 230. In an example, the second photoresist layer 700 and the second patterning process may be similar to the processes described above with respect to FIG. 4 and FIG. 5.

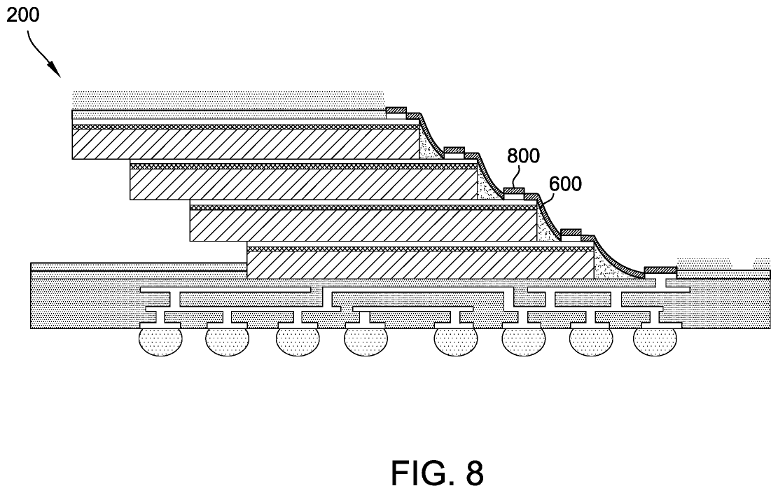

In addition, the sixth operation may also be used to form or expose a plating contact 710 associated with the stack of semiconductor dies 200. The plating contact 710 may be used to facilitate a flow of electric current during a second metal deposition process such as will be described with respect to FIG. 8.

FIG. 8 illustrates a seventh operation in the fabrication process in which an electroplating process is performed on the metal layer 600 according to an example. In an example, the electroplating process is used to form a coating 800 (enlarged for illustrative purposes) or a plate over the exposed metal layer 600. The coating 800 may be formed on the entire metal layer 600 or portions of the metal layer 600. The coating 800 may be used to improve or otherwise enhance the conductivity of the metal layer 600 on the stack of semiconductor dies 200. In an example, the coating 800 is formed of copper. Although copper is specifically mentioned, other conductive materials may be used.

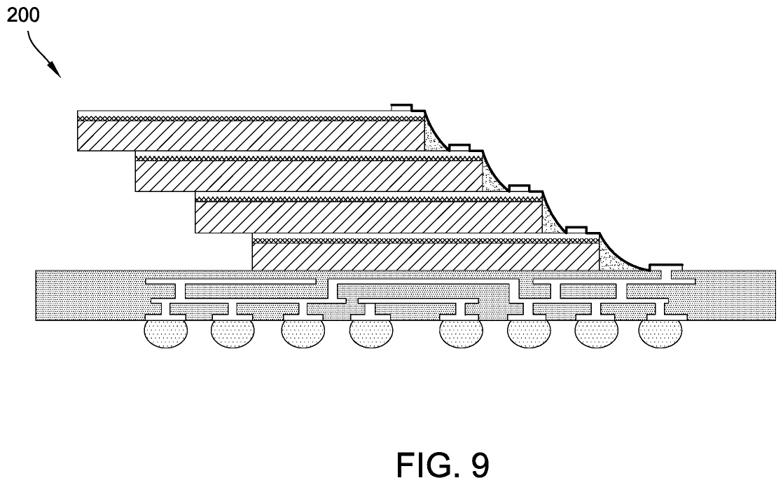

FIG. 9 illustrates an eighth operation in the fabrication process in which the first photoresist layer and the second photoresist layer are removed from the stack of semiconductor dies 200 according to an example. The stack of semiconductor dies 200 shown in FIG. 9 may be used as part of a semiconductor package. In another example, the stack of semiconductor dies 200 may be similar to the stack of semiconductor dies 100 shown and described with respect to FIG. 1.

Accordingly, examples of the present disclosure describe a stack of semiconductor dies for a semiconductor package, comprising: a first semiconductor die; a second semiconductor die stacked on top of the first semiconductor die, the first semiconductor die and the second semiconductor die defining a step corner between a surface of the first semiconductor die and a sidewall of the second semiconductor die; a step ramp formed in the step corner; and a transmission line formed on a first bond pad associated with the first semiconductor die, the step ramp and a second bond pad associated with the second semiconductor die, wherein the transmission line electrically connects the first and second bond pads. In an example, the step ramp is formed from a polymer. In an example, the step ramp forms an approximate forty-five degree angle between the surface of the first semiconductor die and the sidewall of the second semiconductor die. In an example, the step ramp forms less than a forty-five degree angle between the surface of the first semiconductor die and the sidewall of the second semiconductor die. In an example, the stack of semiconductor dies also includes a metal coating provided over the transmission line, the first bond pad and the second bond pad. In an example, the metal coating is copper. In an example, the first semiconductor die is associated with a plurality of bond pads and wherein each of the plurality of bond pads have a pitch of approximately thirty micrometers (μm).

The present application also describes a method for assembling a stack of semiconductor dies for a semiconductor package, comprising: stacking a second semiconductor die on a first semiconductor die to form the stack of semiconductor dies, the first semiconductor die and the second semiconductor die defining a step corner between a surface of the first semiconductor die and a sidewall of the second semiconductor die; forming a step ramp in the step corner; and forming a transmission line over a first bond pad associated with the first semiconductor die, the step ramp and a second bond pad associated with the second semiconductor die, wherein the transmission line electrically connects the first and second bond pads. In an example, the method also includes providing a photoresist layer over the step ramp, the first bond pad and the second bond pad prior to forming the transmission line. In an example, the method also includes preparing the first bond pad and the second bond pad for the transmission line using a laser lithography process based, at least in part, on providing the photoresist layer over the first bond pad and the second bond pad. In an example, the method also includes forming a metal coating over at least a portion of the transmission line, the first bond pad and the second bond pad. In an example, the metal coating is copper. In an example, the step ramp is formed from a polymer.

In another example, a stack of semiconductor dies for a semiconductor package is disclosed. In an example, the stack of semiconductor dies includes a first semiconductor die; a second semiconductor die stacked on top of the first semiconductor die, the first semiconductor die and the second semiconductor die defining a step corner between a surface of the first semiconductor die and a sidewall of the second semiconductor die; a ramp means formed in the step corner; and a transmission means formed on a first connection means associated with the first semiconductor die, the ramp means and a second connection means associated with the second semiconductor die, wherein the transmission means electrically connects the first and second connection means of the first and second semiconductor dies. In an example, the ramp means is formed from a polymer. In an example, the ramp means forms an approximate forty-five degree angle between the surface of the first semiconductor die and the sidewall of the second semiconductor die. In an example, the ramp means forms less than a forty-five degree angle between the surface of the first semiconductor die and the sidewall of the second semiconductor die. In an example, the stack of semiconductor dies of also includes a coating means provided over the transmission means, the first connection means and the second connection means. In an example, the coating means is comprised of copper. In an example, the first semiconductor die is associated with a plurality of connection means and wherein each of the plurality of connection means have a pitch of approximately thirty micrometers (μm).

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features are intended to be selectively rearranged, included or omitted to produce various embodiments with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A stack of semiconductor dies for a semiconductor package, comprising:
a first semiconductor die;
a second semiconductor die stacked on top of the first semiconductor die, the first semiconductor die and the second semiconductor die defining a step corner between a surface of the first semiconductor die and a sidewall of the second semiconductor die;
a step ramp formed in the step corner; and
a transmission line formed on a first bond pad associated with the first semiconductor die, the step ramp and a second bond pad associated with the second semiconductor die, wherein the transmission line electrically connects the first and second bond pads.

2. The stack of semiconductor dies of claim 1, wherein the step ramp is formed from a polymer.

3. The stack of semiconductor dies of claim 1, wherein the step ramp forms an approximate forty-five degree angle between the surface of the first semiconductor die and the sidewall of the second semiconductor die.

4. The stack of semiconductor dies of claim 1, wherein the step ramp forms less than a forty-five degree angle between the surface of the first semiconductor die and the sidewall of the second semiconductor die.

5. The stack of semiconductor dies of claim 1, further comprising a metal coating provided over the transmission line, the first bond pad and the second bond pad.

6. The stack of semiconductor dies of claim 5, wherein the metal coating is copper.

7. The stack of semiconductor dies of claim 1, wherein the first semiconductor die is associated with a plurality of bond pads and wherein each of the plurality of bond pads have a pitch of approximately thirty micrometers (μm).

8. A method for assembling a stack of semiconductor dies for a semiconductor package, comprising:
stacking a second semiconductor die on a first semiconductor die to form the stack of semiconductor dies, the first semiconductor die and the second semiconductor die defining a step corner between a surface of the first semiconductor die and a sidewall of the second semiconductor die;
forming a step ramp in the step corner; and
forming a transmission line over a first bond pad associated with the first semiconductor die, the step ramp and a second bond pad associated with the second semiconductor die, wherein the transmission line electrically connects the first and second bond pads.

9. The method of claim 8, further comprising providing a photoresist layer over the step ramp, the first bond pad and the second bond pad prior to forming the transmission line.

10. The method of claim 9, further comprising preparing the first bond pad and the second bond pad for the transmission line using a laser lithography process based, at least in part, on providing the photoresist layer over the first bond pad and the second bond pad.

11. The method of claim 8, further comprising forming a metal coating over at least a portion of the transmission line, the first bond pad and the second bond pad.

12. The method of claim 11, wherein the metal coating is copper.

13. The method of claim 8, wherein the step ramp is formed from a polymer.

14. A stack of semiconductor dies for a semiconductor package, comprising:
a first semiconductor die;
a second semiconductor die stacked on top of the first semiconductor die, the first semiconductor die and the second semiconductor die defining a step corner between a surface of the first semiconductor die and a sidewall of the second semiconductor die;
a ramp means formed in the step corner; and
a transmission means formed on a first connection means associated with the first semiconductor die, the ramp means and a second connection means associated with the second semiconductor die, wherein the transmission means electrically connects the first and second connection means of the first and second semiconductor dies.

15. The stack of semiconductor dies of claim 14, wherein the ramp means is formed from a polymer.

16. The stack of semiconductor dies of claim 14, wherein the ramp means forms an approximate forty-five degree angle between the surface of the first semiconductor die and the sidewall of the second semiconductor die.

17. The stack of semiconductor dies of claim 14, wherein the ramp means forms less than a forty-five degree angle between the surface of the first semiconductor die and the sidewall of the second semiconductor die.

18. The stack of semiconductor dies of claim 14, further comprising a coating means provided over the transmission means, the first connection means and the second connection means.

19. The stack of semiconductor dies of claim 18, wherein the coating means is comprised of copper.

20. The stack of semiconductor dies of claim 14, wherein the first semiconductor die is associated with a plurality of connection means and wherein each of the plurality of connection means have a pitch of approximately thirty micrometers (μm).
